(19) United States
(12) Patent Application Publication
(10) Pub. No.: US 2008/0252340 A1
(43) Pub. Date: Oct. 16, 2008

(54) DELAY LOCKED LOOP (DLL) CIRCUITS HAVING AN EXPANDED OPERATION RANGE AND METHODS OF OPERATING THE SAME

(75) Inventors: Hwan-seok Yeo, Gyeonggi-do (KR); Jin-ho Seo, Gyeonggi-do (KR); Hong-june Park, Kyungbuk (KR); Jun-hyun Bae, Kyungbuk (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/099,323

(22) Filed: Apr. 8, 2008

(30) Foreign Application Priority Data
Apr. 10, 2007 (KR) 2007-0035013

(51) Int. Cl. H03L 7/06

(52) U.S. Cl. 327/156

(57) ABSTRACT

Delay locked loop (DLL) circuits have a phase detector circuit that can detect a phase difference between an input clock signal and an output clock signal over a time period of 0T-2T. The delay applied to generate the output signal is adjusted based on the detected phase difference. A middle clock signal can be generated that has a phase that is between the input clock signal and the output clock signal. The phase detector circuit may be configured to detect the phase difference between the input clock signal and the output clock signal over the time period 0T-2T responsive to the middle clock signal.

### RELATED APPLICATION

This application claims the benefit of and priority to Korean Patent Application No. 10-2007-0035013, filed Apr. 10, 2007, in the Korean Intellectual Property Office, the disclosure of which is hereby incorporated herein by reference as if set forth in its entirety.

### FIELD OF THE INVENTION

The present invention relates generally to integrated circuit devices and methods of operating the same and, more particularly, to delay locked loop (DLL) circuits, and methods of operating the same.

### BACKGROUND OF THE INVENTION

Delay locked loop (DLL) circuits are clock recovery circuits for precisely synchronizing the phase of an internal clock with the phase of an external clock and are widely applied in a variety of electronic devices including, but not limited to, the next generation of memories or system integrated circuits, such as synchronous dynamic random access memories (SDRAMs) and/or double data rate (DDR) SDRAMs. FIG. 1 illustrates an example in which an external clock leads an internal clock due to skew introduced as a result of the two clock signals traversing different paths.

To precisely synchronize the phase of an internal clock with the phase of an external clock, a phase synchronization device, such as a phase locked loop (PLL) circuit or a DLL is typically used. Where the frequency of an external clock is different from the frequency of an internal clock, a PLL having a frequency multiplication function may be used. On the other hand, where the frequency of an external clock is about the same as that of an internal clock, a DLL may be used. Unlike a PLL, a DLL, typically, does not have a problem with phase noise accumulating and, thus, may be advantageous in decreasing the jitter of an internal clock. Therefore, where frequency multiplication is not necessary, it is relatively common to generate an internal clock using a DLL.

FIG. 2 is a block diagram of a conventional DLL circuit 100. The DLL circuit 100 includes a phase detector 110, an adjustable delay line 120, a delay control unit (DCU) 130, and a compensation delay unit 140 that are configured as shown. The adjustable delay line 120 generates the output clock signal by delaying the input clock signal for a predetermined time. The adjustable delay line may include, for example, a plurality of delay elements, such as inverter circuits, connected in series. The predetermined time is determined by the DCU 130, which generates a digital code for input to the adjustable delay line 120 in response to an output signal generated by the phase detector circuit 110. If an analog design is implemented, then the DCU 130 may output a voltage for input to the adjustable delay line 120 in response to the output signal generated by the phase detector circuit 110. The phase detector circuit 110 generates the output signal for input to the DCU 130 based on the phase difference between the input clock signal and the output clock signal. A compensation delay unit 140 may be used to connect the output clock to the phase detector circuit 110 to approximate the signal path of the output clock signal.

Operation of a phase detector, such as the phase detector 100 of FIG. 2, will now be described with reference to FIGS. 3A and 3B. Referring to FIG. 3A, a phase detector receives a reference signal, such as an input clock signal and a feedback signal, such as an output clock signal, and generates an output pulse signal. As shown in FIG. 3B, the output pulse signal is generated as a positive pulse if the reference signal leads the feedback signal (Case 1). The duty cycle of the positive pulse is based on the amount of time that the reference signal leads the feedback signal. Conversely, when the feedback signal leads the reference signal, the output pulse signal is generated as a negative pulse with a duty cycle based on the amount of time that the feedback signal leads the reference signal.

Referring to FIG. 3C, operations of the conventional DLL circuit 100 of FIG. 2 will be described. In FIG. 3C, the input clock is represented as ICLK and the various output clock scenarios are represented as OCLK1-OCLK4. Two cycles (2 T) 340 of the ICLK signal are shown. The DLL circuit 100 is configured to synchronize the OCLK signal with the ICLK signal at a one-cycle delay 320, i.e., a delay of 1 T. A leading edge transition of the first output clock signal OCLK1 is shown to be leading a leading edge of the ICLK signal 310 between 0.5 T and T. In this case, the phase detector 110 and DCU 130 cause the adjustable delay line 120 to add delay in generating the OCLK1 signal. A leading edge transition of the second output clock signal OCLK2 is shown to be lagging the leading edge of the ICLK signal 310 between T and 1.5 T. In this case, the phase detector 110 and the DCU 130 cause the adjustable delay line 120 to subtract delay in generating the OCLK2 signal. A leading edge transition of the third output clock signal OCLK3 is shown to be leading the leading edge of the ICLK signal 310 between 0 T and 0.5 T. The DLL circuit 100, however, malfunctions in this case and attempts to converge to 0 T instead of 1 T, which is a condition sometimes called “dead lock.” A leading edge transition of the fourth output clock signal OCLK4 is shown to be lagging the leading edge of the ICLK signal 310 between 1.5 T and 2 T. The DLL circuit 100, however, malfunctions in this case and attempts to lock on 2 T or 3 T instead of 1 T, which is a condition sometimes called “false lock.”

Unfortunately, the conventional DLL circuit 100 of FIG. 2 malfunctions when attempting to lock signals that are out of phase in the 0 T-0.5 T range and the 1.5 T-2 T range. As a result, the conventional DLL circuit 100 may not be suitable for use in some high-speed integrated circuit devices.

### SUMMARY

According to some embodiments of the present invention, a phase detector includes a reset circuit that is configured to delay a reset signal responsive to a transition of a middle clock signal, the middle clock signal having a phase between a phase of an input clock signal and a phase of an output clock signal, a clock transition logic circuit that is configured to generate a first output signal responsive to the delayed reset signal and a transition of an input clock signal, and to generate a second output signal responsive to the delayed reset signal and a transition of an output clock signal, and a delay control signal generator circuit that is configured to generate a delay control output signal based on a phase difference between the first and second output signals.

In other embodiments, the reset circuit includes a delay flip-flop.

In still other embodiments, the clock transition logic circuit includes a first toggle flip-flop that is configured to generate the first output signal responsive to the delayed reset signal and the transition of the input clock signal and a second toggle flip-flop that is configured to generate the second output signal responsive to the delayed reset signal and the transition of the output clock signal.

In still other embodiments, the clock transition logic circuit includes a first delay flip-flop that is configured to generate the first output signal responsive to the delayed reset signal and the transition of the input clock signal and a second delay flip-flop that is configured to generate the second output signal responsive to the delayed reset signal and the transition of the output clock signal.

In still other embodiments, the delay control signal generator circuit includes a delay flip-flop.

In still other embodiments, the transitions are of a same type.

In still other embodiments, the transitions are leading edge transitions.

In further embodiments of the present invention, a delay locked loop circuit includes an adjustable delay line that is configured to generate an output clock signal by delaying an input clock signal responsive to a delay control output signal, and is further configured to generate a middle clock signal that has a phase between a phase of the input clock signal and a phase of the output clock signal. The delay locked loop circuit further includes a phase detector that includes a reset circuit that is configured to delay a reset signal responsive to a transition of the middle clock signal, a clock transition logic circuit that is configured to generate a first output signal responsive to the delayed reset signal and a transition of the input clock signal, and to generate a second output signal responsive to the delayed reset signal and a transition of the output clock signal, and a delay control signal generator circuit that is configured to generate the delay control output signal based on a phase difference between the first and second output signals.

In still further embodiments, the delay locked loop circuit further includes a delay control unit that is configured to generate a delay code responsive to the delay control output signal, wherein the adjustable delay line is configured to generate the output clock signal by delaying the input clock signal responsive to the delay code.

In still further embodiments, the delay locked loop circuit further includes a delay control unit that includes a charge pump that is configured to generate a current responsive to the delay control output signal and a loop filter that is configured to generate a delay control voltage responsive to the generated current, wherein the adjustable delay line is configured to generate the output clock signal by delaying the input clock signal responsive to the delay control voltage.

In still further embodiments, the reset circuit includes a delay flip-flop.

In still further embodiments, the clock transition logic circuit includes a first toggle flip-flop that is configured to generate the first output signal responsive to the delayed reset signal and the transition of the input clock signal and a second toggle flip-flop that is configured to generate the second output signal responsive to the delayed reset signal and the transition of the output clock signal.

In still further embodiments, the clock transition logic circuit includes a first delay flip-flop that is configured to generate the first output signal responsive to the delayed reset signal and the transition of the input clock signal and a second delay flip-flop that is configured to generate the second output signal responsive to the delayed reset signal and the transition of the output clock signal.

In still further embodiments, the delay control signal generator circuit includes a delay flip-flop.

In still further embodiments, the transitions are of a same type.

In still further embodiments, the transitions are leading edge transitions.

In other embodiments of the present invention, an integrated circuit device includes logic configured to detect a phase difference between an input clock signal and an output clock signal over a time period of 0 to 2 T where T is a cycle time of both the input clock signal and the output clock signal and an adjustable delay line that is configured to generate the output clock signal responsive to the detected phase difference.

In still other embodiments, the integrated circuit device is an integrated circuit memory device.

In still other embodiments, the integrated circuit device includes a memory controller circuit, a memory cell array, and a data driver circuit that is configured to output data from the memory cell array to the memory controller circuit responsive to the output clock signal.

In still other embodiments, the integrated circuit memory device is a DRAM, SRAM, MRAM, PRAM, or Flash device.

In further embodiments of the present invention, a system includes a controller circuit and at least one integrated circuit device connected to the controller circuit. The at least one integrated circuit device includes logic configured to detect a phase difference between an input clock signal and an output clock signal over a time period of 0 to 2 T where T is a cycle time of both the input clock signal and the output clock signal and an adjustable delay line that is configured to generate the output clock signal responsive to the detected phase difference.

Although described above primarily with respect to device, circuit, and/or system embodiments of the present invention, it will be understood that the present invention can be embodied as a device, system, circuit, and/or method.

### BRIEF DESCRIPTION OF THE DRAWINGS

Other features of the present invention will be more readily understood from the following detailed description of specific embodiments thereof when read in conjunction with the accompanying drawings, in which:

FIG. 1 is a block diagram that illustrates skew between an external clock signal and an internal clock signal;

FIG. 2 is a block diagram of a conventional delay locked loop (DLL) circuit;

FIGS. 3A-3C are signal waveform diagrams that illustrate operations of the DLL circuit of FIG. 2;

FIG. 4 is a block diagram of a DLL circuit in accordance with some embodiments of the present invention;

FIG. 5 is a circuit schematic of a phase detector circuit used in the DLL circuit of FIG. 4 in accordance with some embodiments of the present invention;

FIGS. 6-7 are signal waveform diagrams that illustrate operations of the DLL circuit of FIG. 5 in accordance with some embodiments of the present invention;

FIGS. 8A-8B are signal waveform diagrams that illustrate differences in operation between a DLL circuit in accordance with some embodiments of the present invention and a conventional DLL circuit;

FIG. 9 is a circuit schematic of a phase detector circuit used in the DLL circuit of FIG. 4 in accordance with further embodiments of the present invention;

FIGS. 10-11 are block diagrams of DLL circuits in accordance with further embodiments of the present invention; and

FIGS. 12-15 are block diagrams of various devices, circuits, and systems that use a DLL circuit in accordance with some embodiment of the present invention.

### DETAILED DESCRIPTION OF EMBODIMENTS

While the present invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention as defined by the claims.

It will be understood that when an element is referred to as being “connected to” or “coupled to” another element, it can be directly connected or coupled to the other element or intervening elements may be present. In contrast, when an element is referred to as being “directly connected to” or “directly coupled to” another element, there are no intervening elements. As used herein, the term “and/or” and “/” includes any and all combinations of one or more of the associated listed items. Like numbers refer to like elements throughout the description.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that although the terms first and second are used herein to describe various components, circuits, regions, layers and/or sections, these components, circuits, regions, layers and/or sections should not be limited by these terms. These terms are only used to distinguish one component, circuit, region, layer or section from another component, circuit, region, layer or section. Thus, a first component, circuit, region, layer or section discussed below could be termed a second component, circuit, region, layer or section, and similarly, a second component, circuit, region, layer or section may be termed a first component, circuit, region, layer or section without departing from the teachings of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

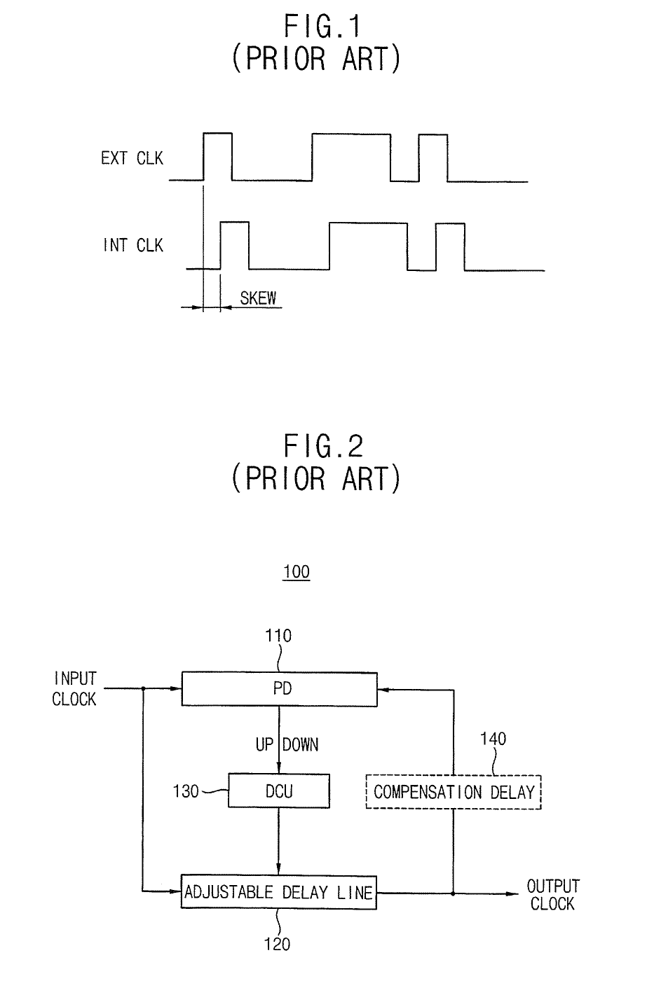

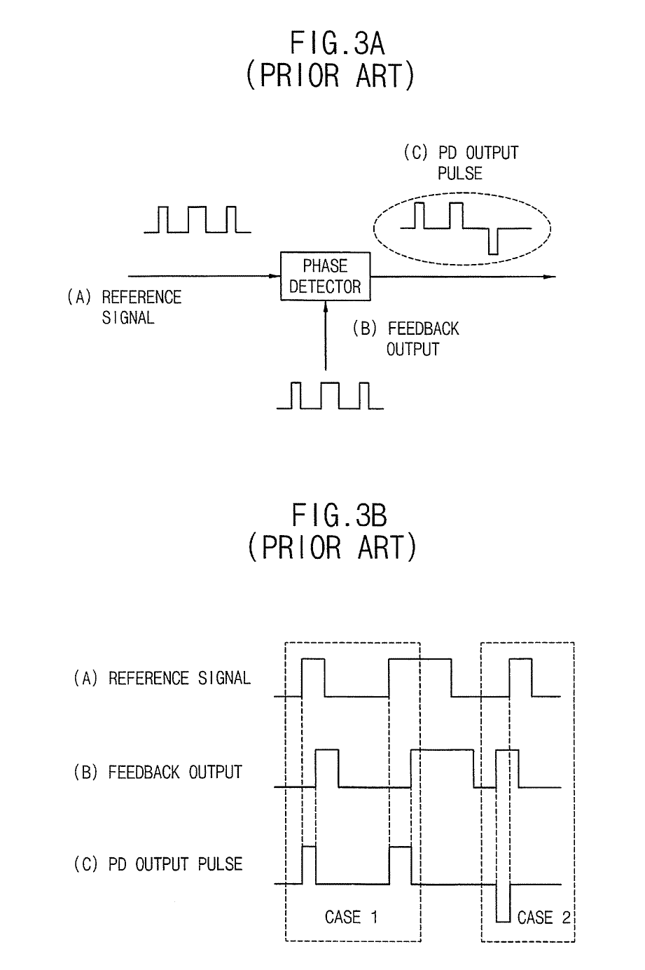

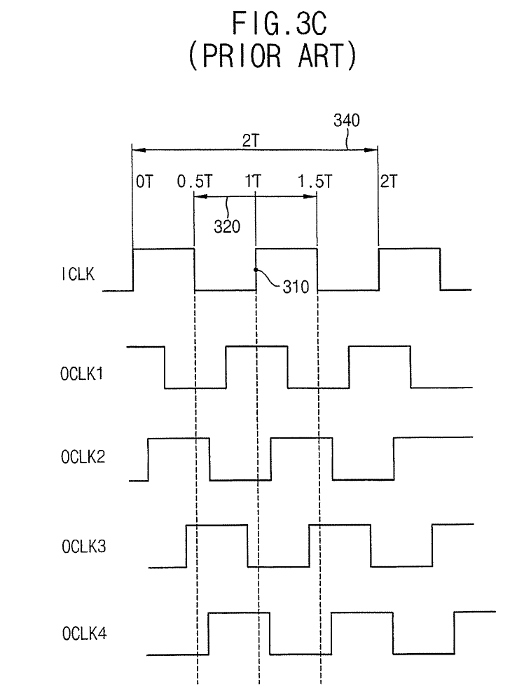

In contrast with conventional delay locked loop (DLL) circuits as described above with respect to FIG. 2 in which the phase detector circuit malfunctions when trying to lock two signals that are out of phase in the 0 T-0.5 T (T is the signal cycle time, i.e., one period) range and the 1.5 T-2 T range, some embodiments of the present invention provide DLL circuits having a phase detector circuit that can detect a phase difference between an input clock signal and an output clock signal over a time period of 0 T-2 T. The delay applied to generate the output signal is adjusted based on the detected phase difference. In particular embodiments, a middle clock signal can be generated that has a phase that is between the input clock signal and the output clock signal. The phase detector circuit may be configured to detect the phase difference between the input clock signal and the output clock signal over the time period 0 T-2 T responsive to the middle clock signal. The ability to detect a phase difference between the input and output clock signals over a full two periods may allow DLL circuits, according to some embodiments of the present invention, to be used in higher frequency devices and/or systems.

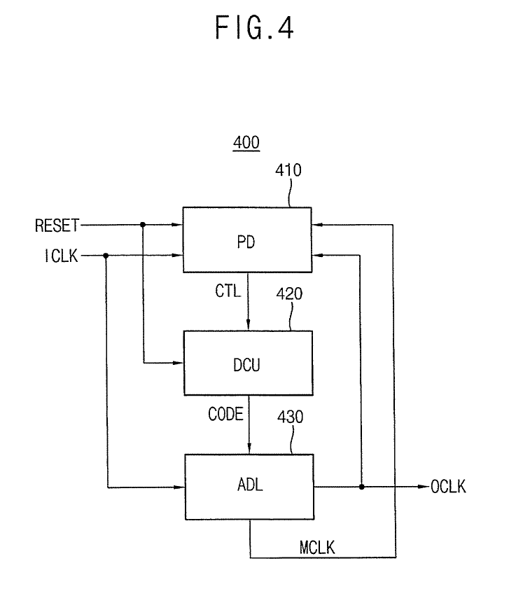

Referring to FIG. 4, a DLL circuit 400, according to some embodiments of the present invention, comprises a phase detector circuit 410, a delay control unit (DCU) 420, and an adjustable delay line (ADL) 430 that are configured as shown. The phase detector 410 is configured to generate a control signal responsive to an input clock signal (ICLK), an output clock signal (OCLK), a middle clock signal (MCLK), and a reset signal (RESET). The DCU 420 is configured to generate a digital CODE in response to the control signal CTL output from the phase detector 410. The digital CODE specifies the amount of delay to be applied to the input clock signal ICLK in generating the output clock signal (OCLK). The ADL 430 generates both the output clock signal (OCLK) and the middle clock signal (MCLK) responsive to the input clock signal (ICLK) with the digital CODE output from the DCU 420. The middle clock signal (MCLK) is generated so as to have a phase between that of the input clock signal (ICLK) and the output clock signal (OCLK).

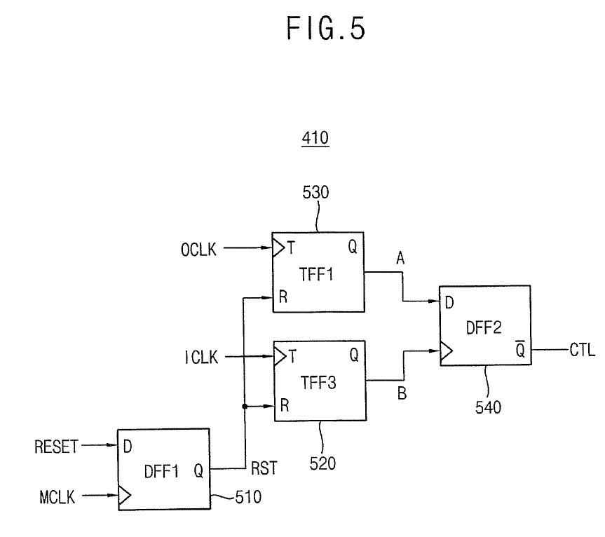

FIG. 5 is a circuit schematic that illustrates the phase detector 410 in more detail in accordance with some embodiments of the present invention. The phase detector 410 comprises a reset circuit 510, a clock transition logic circuit that includes two toggle flip-flops 520 and 530, and a delay control signal generator circuit 540. The reset circuit 510 comprises a delay flip-flop that generates a reset signal (RST) in response to the reset signal RESET and the middle clock signal MCLK. The first toggle flip-flop 520 generates an output signal B responsive to the delayed RESET signal RST and the input clock signal ICLK. The second toggle flip-flop 530 generates an output signal A responsive to the delayed RESET signal RST and the output clock signal OCLK. The delay control signal generator circuit 540 comprises a delay flip-flop that generates the control signal CTL responsive to the output signals A and B from the clock transition logic circuit.

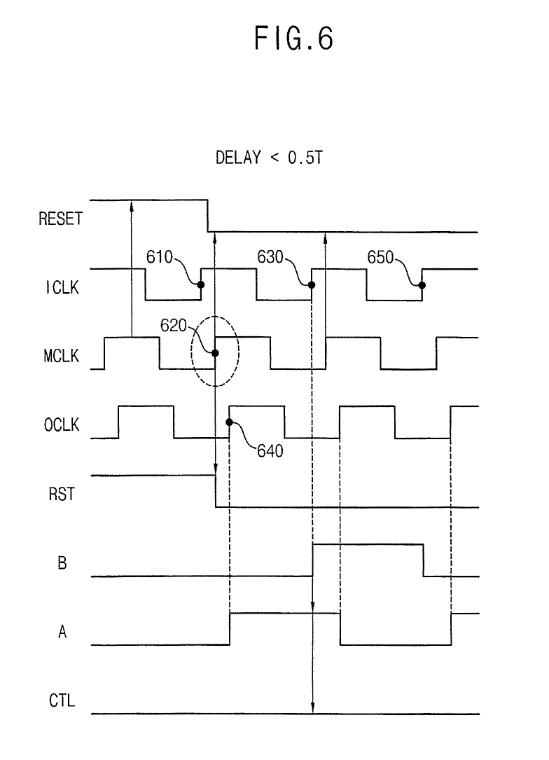

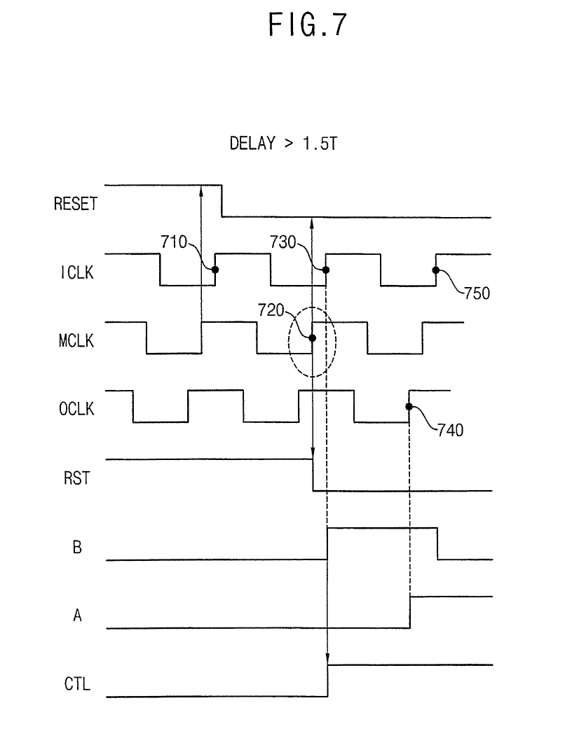

Exemplary operations of the phase detector circuit 410 of FIGS. 4 and 5 will be described with reference to FIGS. 6 and 7. FIG. 6 illustrates exemplary operations of the phase detector circuit 410 for the case in which the input clock signal ICLK and the output clock signal OCLK are out of phase in the 0 T-0.5 T range. The input clock signal ICLK transitions from low to high at time 610. The RESET signal transitions from high to low soon thereafter and the delayed RESET signal RST transitions from high to low upon a transition of the middle clock signal MCLK from low to high at time 620. The middle clock signal has a phase that is between the input clock signal ICLK and the output clock signal OCLK. Upon the transition of the delayed RESET signal RST from high to low, the next leading edge transition of the output clock signal OCLK is transferred to the output of the flip-flop 530 of FIG. 5 as signal A at time 640. Similarly, the next leading edge transition of the input clock signal ICLK is transferred to the output of the flip-flop 520 as signal B at time 630. Signal B acts as the clock signal for the flip-flop 540 of FIG. 5 to output the complement of the state of signal A as the control signal CTL for the DCU 420. In this case, the CTL signal remains low causing the DCU 420 to generate a code for the adjustable delay line 430 to add delay in generating the output clock signal OCLK because the output clock signal OCLK is leading the input clock signal ICLK. Time 650 marks completion of a second cycle of the input clock signal ICLK. Thus, in contrast with the conventional DLL circuit 100 discussed above with respect to FIG. 2, a DLL circuit 400, according to some embodiments of the present invention, can properly handle the situation in which the input clock signal ICLK and the output clock signal OCLK are out of phase in the 0 T-0.5 T range.

FIG. 7 illustrates exemplary operations of the phase detector circuit 410 for the case in which the input clock signal ICLK and the output clock signal OCLK are out of phase in the 1.5 T-2 T range. The input clock signal ICLK transitions from low to high at time 710. The RESET signal transitions from high to low soon thereafter and the delayed RESET signal RST transitions from high to low upon a transition of the middle clock signal MCLK from low to high at time 720. Upon the transition of the delayed RESET signal RST from high to low, the next leading edge transition of the input clock signal ICLK is transferred to the output of the flip-flop 520 as signal B at time 730. Signal B acts as the clock signal for the flip-flop 540 of FIG. 5 to output the complement of the state of signal A as the control signal CTL for the DCU 420. In this case, the CTL signal transitions high causing the DCU 420 to generate a code for the adjustable delay line 430 to subtract delay in generating the output clock signal OCLK because the output clock signal OCLK is lagging the input clock signal ICLK. The next leading edge transition of the output clock signal OCLK after the transition of the RST signal from high is transferred to the output of the flip-flop 530 as signal A at time 740, but this does not cause a transition in the control signal CTL. Time 750 marks completion of a second cycle of the input clock signal ICLK. Thus, in contrast with the conventional DLL circuit 100 discussed above with respect to FIG. 2, a DLL circuit 400, according to some embodiments of the present invention, can properly handle the situation in which the input clock signal ICLK and the output clock signal OCLK are out of phase in the 1.5 T-2 T range.

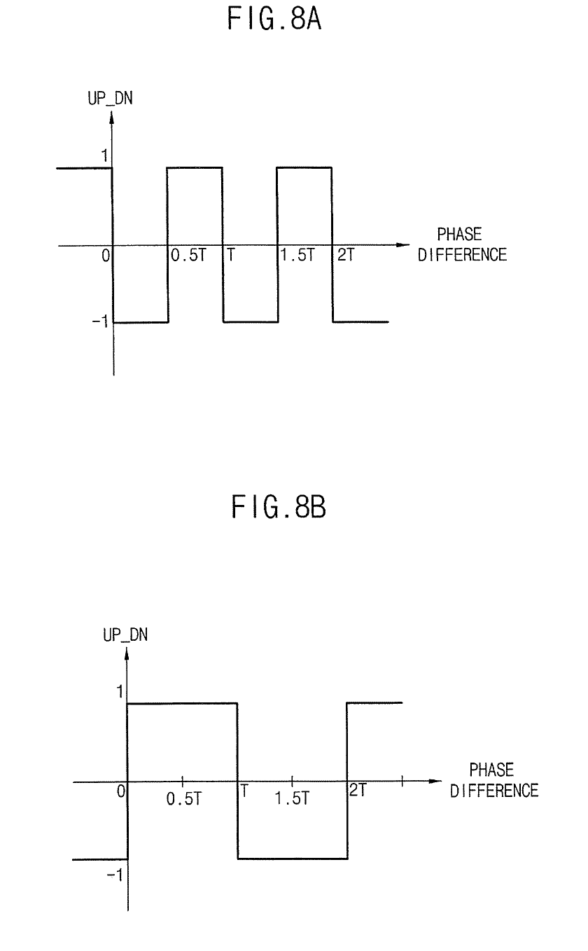

As shown in FIG. 8A, conventional DLL circuits as described above with respect to FIG. 2 malfunction when trying to lock two signals that are harmonically locked in the 0 T-0.5 T range and the 1.5 T-2 T range. By contrast, as shown in FIG. 8B, some embodiments of the present invention provide DLL circuits having a phase detector circuit that can detect a phase difference between an input clock signal and an output clock signal over a time period of 0 T-2 T. The ability to detect a phase difference between the input and output clock signals over a full two periods may allow DLL circuits, according to some embodiments of the present invention, to be used in higher or lower frequency devices and/or systems.

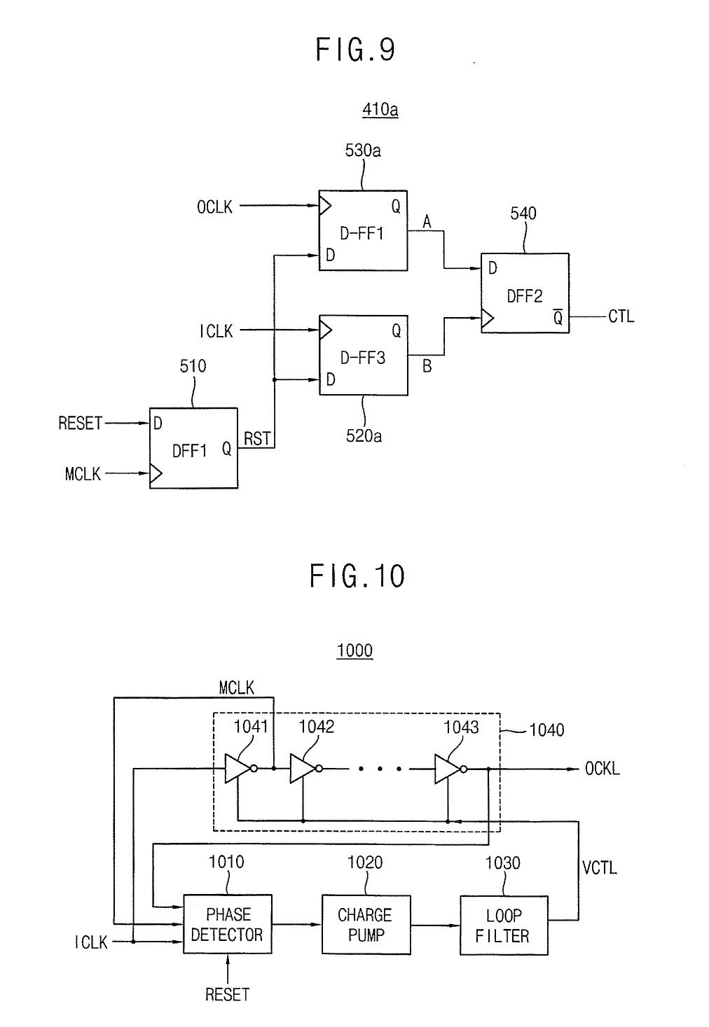

Referring to FIG. 9, a phase detector circuit 410a, in accordance with further embodiments of the present invention, will be described. The phase detector circuit 410a is configured the same as the phase detector circuit of FIG. 5 with the exception being that the toggle flip-flops 520 and 530 that are used in the clock transition logic circuit of FIG. 5 are replaced with delay flip-flops 520a and 530a as shown in FIG. 9. The toggle flip-flops 520 and 530 of the FIG. 5 embodiments are operable as a frequency divider, i.e., to divide the clock frequency in half. Accordingly, the FIG. 5 embodiments may be desirable for use in high frequency devices. By contrast, the delay flip-flops 520a and 530a of the FIG. 9 embodiments to not provide frequency division. Accordingly, the FIG. 9 embodiments may be desirable for use in devices in which frequency division is not needed.

The DLL circuit 410 of FIG. 4 uses a DCU circuit 420 that generates a digital CODE signal for input to the adjustable delay line 430. In other embodiments of the present invention, a DLL circuit, according to some embodiments of the present invention, may be implemented using analog circuitry. Referring to FIG. 10, a DLL circuit 1000 comprises a phase detector circuit 1010, a charge pump 1020, a loop filter 1030, and an adjustable delay circuit 1040 that are configured as shown. The DLL circuit 1000 generates an output clock signal OCLK by delaying an input clock signal ICLK for a predetermined time using the adjustable delay circuit 1040. The adjustable delay circuit 1040 comprises a plurality of inverters 1041 through 1043, which are connected in series, as delay elements, and generates an output clock signal OCLK by delaying the input clock signal ICLK for a predetermined time. The predetermined time is determined by the voltage level of a delay control signal VCTL, which is generated by the loop filter 1030. The phase detector 1010 is configured to generate a control signal responsive to the input clock signal ICLK, the output clock signal OCLK, a middle clock signal MCLK, and a reset signal RESET as discussed above with respect to FIGS. 5-7 and 9. The delay applied to generate the middle clock signal MCLK may vary in accordance with different embodiments of the present invention. In some embodiments, the delay applied to generate the middle clock signal MCLK may be about one-half the delay used to generate the output clock signal OCLK, which may provide a relatively stable margin. The charge pump 1020 generates a current responsive to the control signal output from the phase detector circuit 1010, and the loop filter 1030 generates the delay control signal VCTL with a voltage level corresponding to the current generated by the charge pump 1020.

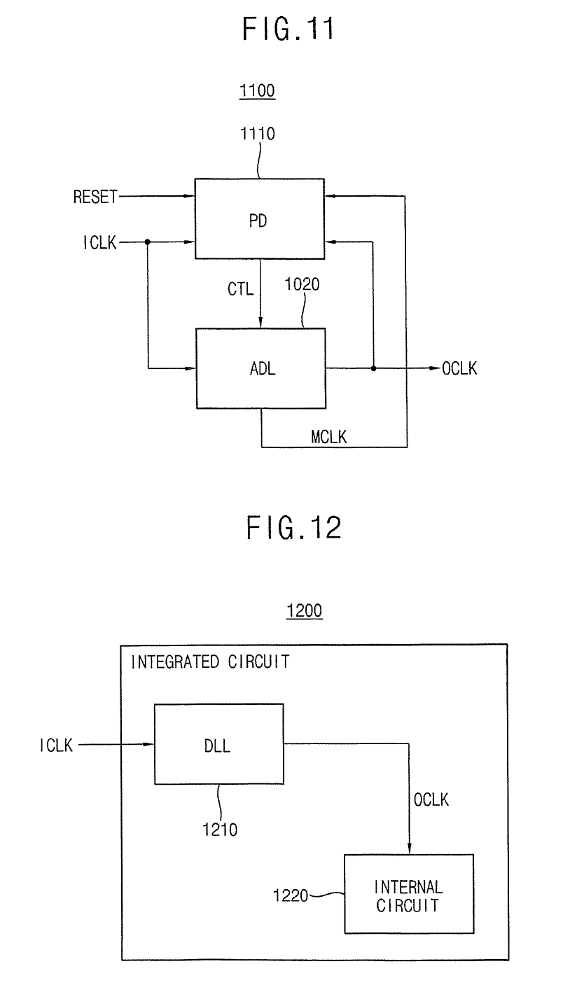

In other embodiments of the present invention shown in FIG. 11, a DLL circuit 1100 may comprise a phase detector circuit 1110 as described above with respect to FIGS. 5-7 and 9 and an adjustable delay line 1120 that are configured as shown. In contrast with the embodiments of FIGS. 4 and 10, the DLL circuit 1100 does not incorporate a DCU circuit or analog circuitry, such as a charge pump and loop filter, as an interface between the phase detector circuit 1110 and the adjustable delay line 1120. Instead, the adjustable delay line 1120 is directly responsive to the control signal CTL output from the phase detector circuit 1110.

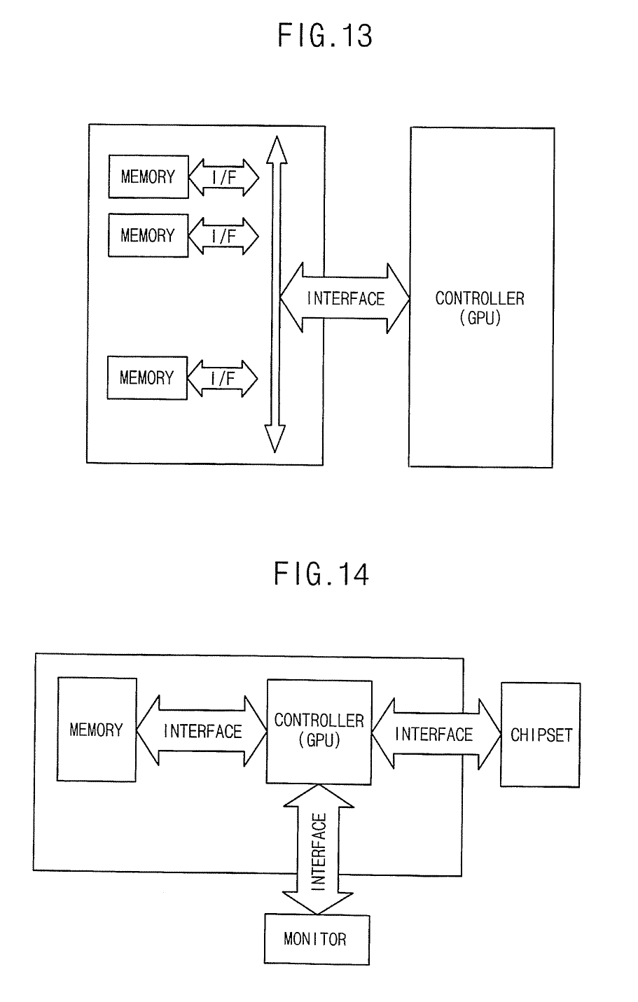

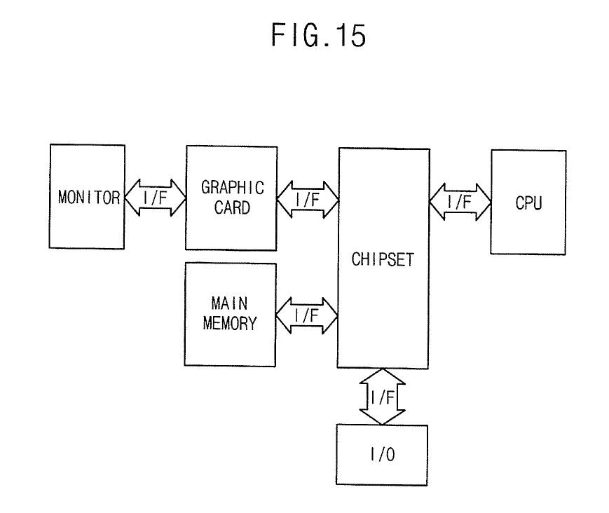

Referring to FIG. 12, an integrated circuit device 1200 may comprise a DLL circuit 1210 in accordance with the embodiments described above with respect to FIGS. 4-11 that is connected to an internal circuit 1220. The DLL circuit 1210 is configured to generate an output clock signal OCLK responsive to an input clock signal ICLK. As shown in FIG. 13, the integrated circuit device 1200 may be an integrated circuit memory device that may be accessed via a controller. In accordance with various embodiments of the present invention, the integrated circuit memory device may be a DRAM, SRAM, MRAM, PRAM, and/or Flash memory device. As shown in FIG. 14, the integrated circuit device of FIG. 12 may be used in various circuitry comprising a graphics card, including, for example, the memory circuitry and/or the controller circuitry. The controller circuitry may be used to interface with a chipset and/or a monitor, which may also incorporate an integrated circuit 1200 having a DLL circuit 1210 in accordance with some embodiments of the present invention. Referring to FIG. 15, the integrated circuit device of FIG. 12 may be used in various circuitry comprising a computer or other electronic device, such as a mobile terminal. The integrated circuit device of FIG. 12 including a DLL circuit 1210, in accordance with some embodiments of the present invention, may be used in a CPU circuit, chipset, graphics card, memory module, monitor, and/or I/O circuit.

In concluding the detailed description, it should be noted that many variations and modifications can be made to the embodiments without substantially departing from the principles of the present invention. All such variations and modifications are intended to be included herein within the scope of the present invention, as set forth in the following claims.

That which is claimed:

1. A phase detector, comprising:
a reset circuit that is configured to delay a reset signal responsive to a transition of a middle clock signal, the middle clock signal having a phase between a phase of an input clock signal and a phase of an output clock signal;
a clock transition logic circuit that is configured to generate a first output signal responsive to the delayed reset signal and a transition of an input clock signal, and to generate a second output signal responsive to the delayed reset signal and a transition of an output clock signal; and
a delay control signal generator circuit that is configured to generate a delay control output signal based on a phase difference between the first and second output signals.

2. The phase detector of claim 1 wherein the reset circuit comprises a delay flip-flop.

3. The phase detector of claim 1, wherein the clock transition logic circuit comprises:
a first toggle flip-flop that is configured to generate the first output signal responsive to the delayed reset signal and the transition of the input clock signal; and
a second toggle flip-flop that is configured to generate the second output signal responsive to the delayed reset signal and the transition of the output clock signal.

4. The phase detector of claim 1, wherein the clock transition logic circuit comprises:
a first delay flip-flop that is configured to generate the first output signal responsive to the delayed reset signal and the transition of the input clock signal; and
a second delay flip-flop that is configured to generate the second output signal responsive to the delayed reset signal and the transition of the output clock signal.

5. The phase detector of claim 1, wherein the delay control signal generator circuit comprises a delay flip-flop.

6. The phase detector of claim 1, wherein the transitions are of a same type.

7. The phase detector of claim 6, wherein the transitions are leading edge transitions.

8. A delay locked loop circuit, comprising:
an adjustable delay line that is configured to generate an output clock signal by delaying an input clock signal responsive to a delay control output signal, and is further configured to generate a middle clock signal that has a phase between a phase of the input clock signal and a phase of the output clock signal; and
a phase detector, comprising:
a reset circuit that is configured to delay a reset signal responsive to a transition of the middle clock signal;
a clock transition logic circuit that is configured to generate a first output signal responsive to the delayed reset signal and a transition of the input clock signal, and to generate a second output signal responsive to the delayed reset signal and a transition of the output clock signal; and
a delay control signal generator circuit that is configured to generate the delay control output signal based on a phase difference between the first and second output signals.

9. The delay locked loop circuit of claim 8, further comprising:
a delay control unit that is configured to generate a delay code responsive to the delay control output signal; and
wherein the adjustable delay line is configured to generate the output clock signal by delaying the input clock signal responsive to the delay code.

10. The delay locked loop circuit of claim 8, further comprising:
a delay control unit, comprising:
a charge pump that is configured to generate a current responsive to the delay control output signal; and
a loop filter that is configured to generate a delay control voltage responsive to the generated current;
wherein the adjustable delay line is configured to generate the output clock signal by delaying the input clock signal responsive to the delay control voltage.

11. The delay locked loop circuit of claim 8, wherein the reset circuit comprises a delay flip-flop.

12. The delayed locked loop circuit of claim 8, wherein the clock transition logic circuit comprises:
a first toggle flip-flop that is configured to generate the first output signal responsive to the delayed reset signal and the transition of the input clock signal; and
a second toggle flip-flop that is configured to generate the second output signal responsive to the delayed reset signal and the transition of the output clock signal.

13. The delayed locked loop circuit of claim 8, wherein the clock transition logic circuit comprises:
a first delay flip-flop that is configured to generate the first output signal responsive to the delayed reset signal and the transition of the input clock signal; and
a second delay flip-flop that is configured to generate the second output signal responsive to the delayed reset signal and the transition of the output clock signal.

14. The delayed locked loop circuit of claim 8, wherein the delay control signal generator circuit comprises a delay flip-flop.

15. The phase detector of claim 8, wherein the transitions are of a same type.

16. The phase detector of claim 15, wherein the transitions are leading edge transitions.

17. A method of operating a phase detector, comprising:
delaying a reset signal responsive to a transition of a middle clock signal, the middle clock signal having a phase between a phase of an input clock signal and a phase of an output clock signal;
generating a first output signal responsive to the delayed reset signal and a transition of an input clock signal;
generating a second output signal responsive to the delayed reset signal and a transition of an output clock signal; and
generating a delay control output signal based on a phase difference between the first and second output signals.

18. The method of claim 17, wherein delaying the reset signal comprises delaying the reset signal using a delay flip-flop.

19. The method of claim 17, wherein generating the first output signal comprises generating the first output signal using a first toggle flip-flop; and wherein generating the second output signal comprises generating the second output signal using a second toggle flip-flop.

20. The method of claim 17, wherein generating the first output signal comprises generating the first output signal using a first delay flip-flop; and wherein generating the second output signal comprises generating the second output signal using a second delay flip-flop.

21. The method of claim 17, wherein generating the delay control output signal comprises generating the delay control output signal using a delay flip-flop.

22. The method of claim 17, wherein the transitions are of a same type.

23. The method of claim 22, wherein the transitions are leading edge transitions.

24. A method of operating a delay locked loop circuit, comprising:
delaying an input clock signal responsive to a delay control output signal to generate an output clock signal;
generating a middle clock signal that has a phase between a phase of the input clock signal and a phase of the output clock signal;
delaying a reset signal responsive to a transition of the middle clock signal;
generating a first output signal responsive to the delayed reset signal and a transition of the input clock signal;
generating a second output signal responsive to the delayed reset signal and a transition of the output clock signal; and
generating the delay control output signal based on a phase difference between the first and second output signals.

25. The method of claim 24, further comprising:
generating a delay code responsive to the delay control output signal; and
wherein generating the output clock signal comprises delaying the input clock signal responsive to the delay code.

26. The method of claim 24, further comprising:
generating a current responsive to the delay control output signal; and
generating a delay control voltage responsive to the generated current;
wherein generating the output clock signal comprises delaying the input clock signal responsive to the delay control voltage.

27. The method of claim 24, wherein delaying the reset signal comprises delaying the reset signal using a delay flip-flop.

28. The method of claim 24, wherein generating the first output signal comprises generating the first output signal using a first toggle flip-flop; and wherein generating the second output signal comprises generating the second output signal using a second toggle flip-flop.

29. The method of claim 24, wherein generating the first output signal comprises generating the first output signal using a first delay flip-flop; and wherein generating the second output signal comprises generating the second output signal using a second delay flip-flop.

30. The method of claim 24, wherein generating the delay control output signal comprises generating the delay control output signal using a delay flip-flop.

31. The method of claim 24, wherein the transitions are of a same type.

32. The method of claim 30, wherein the transitions are leading edge transitions.

33. A method of operating a phase detector circuit, comprising:
detecting a phase difference between an input clock signal and an output clock signal over a time period of 0 to 2 T where T is a cycle time of both the input clock signal and the output clock signal.

34. The method of claim 33, further comprising:
generating a middle clock signal having a phase between a phase of the input clock signal and a phase of the output clock signal;
wherein detecting the phase difference comprises:
detecting the phase difference between the input clock signal and the output clock signal responsive to the middle clock signal.

35. The method of claim 34, further comprising:
generating a first output signal responsive to the middle clock signal and the input clock signal; and
generating a second output signal responsive to the middle clock signal and the output clock signal;
wherein detecting the phase difference comprises:
detecting the phase difference between the input clock signal and the output clock signal based on a phase difference between the first output signal and the second output signal.

36. A method of operating a DLL, comprising:
detecting a phase difference between an input clock signal and an output clock signal over a time period of 0 to 2 T where T is a cycle time of both the input clock signal and the output clock signal; and
adjusting a delay applied to generate the output clock signal based on the detected phase difference.

37. The method of claim 36, further comprising:
generating a delay code responsive to the detected phase difference; and
delaying the input clock signal responsive to the delay code to generate the output clock signal.

38. The method of claim 36, further comprising:
generating a current responsive to the detected phase difference;
generating a delay control voltage responsive to the generated current; and
delaying the input clock signal responsive to the delay control voltage to generate the output clock signal.

39. An integrated circuit device, comprising:
logic configured to detect a phase difference between an input clock signal and an output clock signal over a time period of 0 to 2 T where T is a cycle time of both the input clock signal and the output clock signal; and
an adjustable delay line that is configured to generate the output clock signal responsive to the detected phase difference.

40. The integrated circuit device of claim 39, wherein the integrated circuit device is an integrated circuit memory device.

41. The integrated circuit device of claim 40, further comprising:
a memory controller circuit;
a memory cell array; and
a data driver circuit that is configured to output data from the memory cell array to the memory controller circuit responsive to the output clock signal.

42. The integrated circuit device of claim 40, wherein the integrated circuit memory device is a DRAM, SRAM, MRAM, PRAM, or Flash device.

43. A system, comprising:
a controller circuit;
at least one integrated circuit device connected to the controller circuit, the at least one integrated circuit device comprising:
logic configured to detect a phase difference between an input clock signal and an output clock signal over a time period of 0 to 2 T where T is a cycle time of both the input clock signal and the output clock signal; and
an adjustable delay line that is configured to generate the output clock signal responsive to the detected phase difference.

44. The system of claim 43, wherein the at least one integrated circuit device is an integrated circuit memory device.

45. The system of claim 43, wherein the system comprises a graphics card, a computer, and/or a mobile terminal.

46. A system, comprising:
a plurality of integrated circuit devices, at least one of the integrated circuit devices comprising:
logic configured to detect a phase difference between an input clock signal and an output clock signal over a time period of 0 to 2 T where T is a cycle time of both the input clock signal and the output clock signal; and
an adjustable delay line that is configured to generate the output clock signal responsive to the detected phase difference.

47. The system of claim 46, wherein the system is a memory module and the at least one of the integrated circuit devices is a memory device.
